(19) United States
(12) Patent Application Publication
(10) Pub. No.: US 2014/0085781 A1
(43) Pub. Date: Mar. 27, 2014

(54) BUTTON ASSEMBLY AND ELECTRONIC DEVICE USING THE SAME

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: SONG-QI ZENG, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/723,211

(22) Filed: Dec. 21, 2012

(30) Foreign Application Priority Data
Sep. 27, 2012 (CN) 201210373359.4

(51) Int. Cl. H01R 4/70; H05K 5/06

(52) U.S. Cl. CPC H01R 4/70; H05K 5/061
USPC 361/679.01; 174/138 F

(57) ABSTRACT

An electronic device includes a housing defining an opening, a button body and a sealing member. The button body includes a cap member, a key rod, a resisting rod, and a protruding member. The protruding member protrudes from a lateral surface of the resisting rod. The protruding member includes a resisting surface. The sealing member is integrally formed with the housing at the opening. The sealing member includes a main body arranged in the opening and a positioning member protruding from the main body. The positioning member defines a receiving hole including an opening end. The key rod is inserted into the receiving hole through the opening end. The sealing member defines a first through hole. The resisting rod extends through the first through hole, the sealing member is urged to elastically deform by the resisting surface, and the first through hole is tightly engaged with the resisting rod.

### BACKGROUND

1. Technical Field

The present disclosure relates to button assemblies and electronic devices using the same, and particularly to a waterproof button assembly and electronic device using the same.

2. Description of Related Art

Electronic devices such as cell phones often include a number of mechanical button assemblies. Due to the gap between the button assemblies and the housing of the device, water may enter the device.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is a schematic view of an electronic device in accordance with an exemplary embodiment.

FIG. 2 is a partial, exploded view of the electronic device of FIG. 1 in a first embodiment.

FIG. 3 is similar to FIG. 2, but viewed from another perspective.

FIG. 4 is a schematic cross-section view of the electronic device of FIG. 3.

FIG. 5 is similar to FIG. 4, but viewed from another perspective.

FIG. 6 is a partial, exploded view of the electronic device of FIG. 1 in a second embodiment.

FIG. 7 is a schematic cross-section view of the electronic device of FIG. 6.

FIG. 8 is similar to FIG. 7, but viewed from another perspective.

### DETAILED DESCRIPTION

The embodiments of the present disclosure are described with reference to the accompanying drawings.

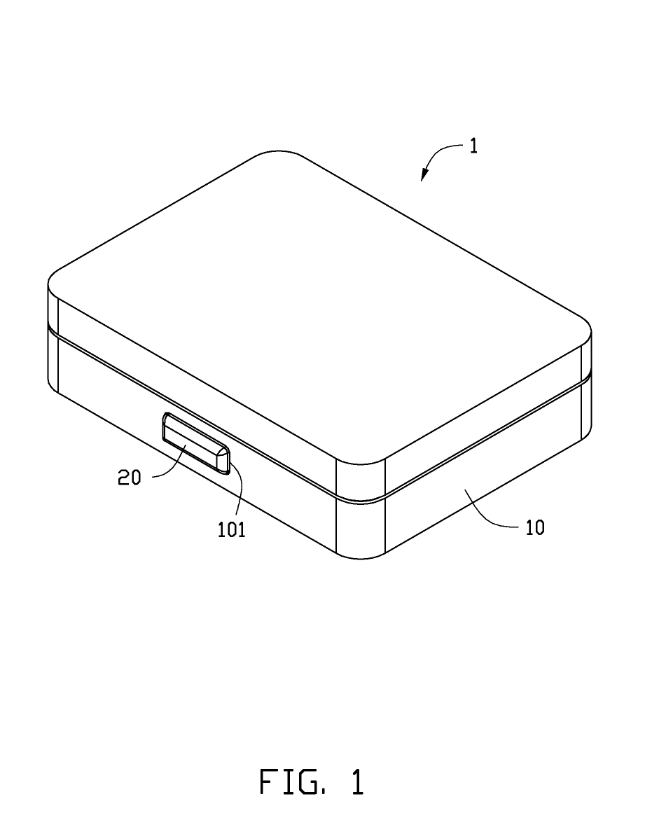

FIG. 1 shows an electronic device 1 in accordance with an exemplary embodiment. The electronic device 1 includes a housing 10 and a button assembly 20. The housing 10 defines an opening 101. The button assembly 20 is movably connected to the housing 10. When the button assembly 20 is pressed, a PCB board (not labeled) arranged in the housing 10 generates a signal accordingly.

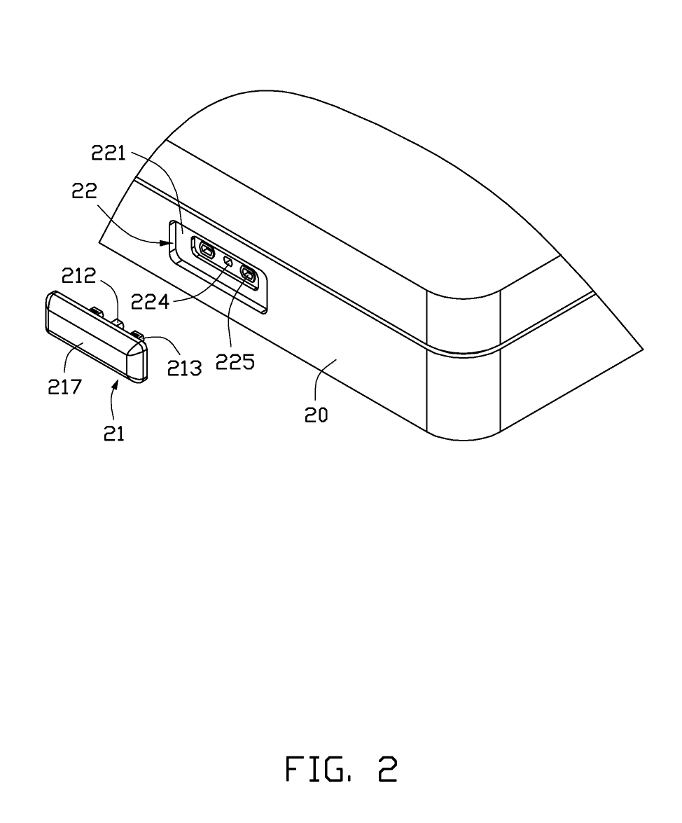

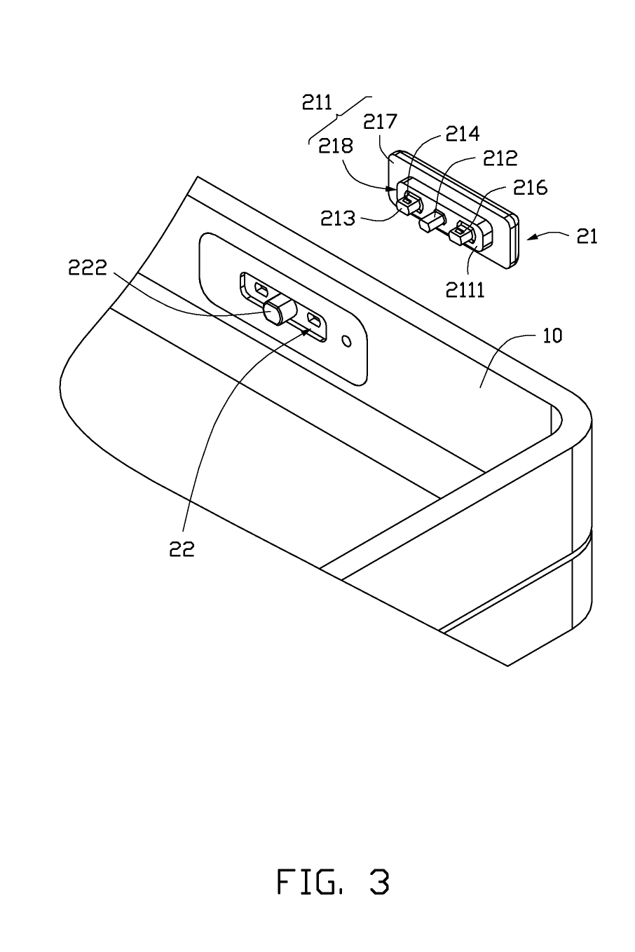

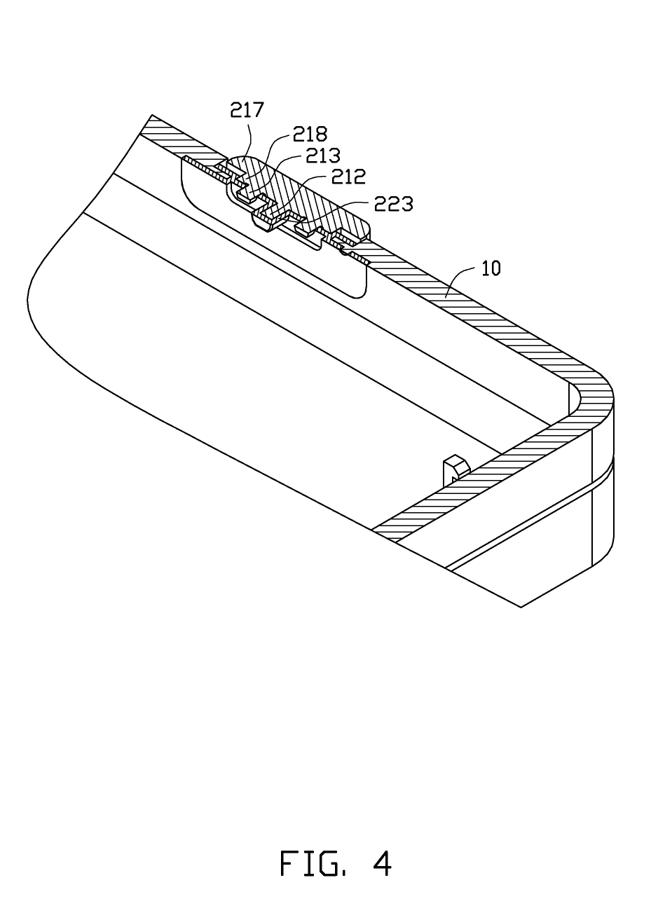

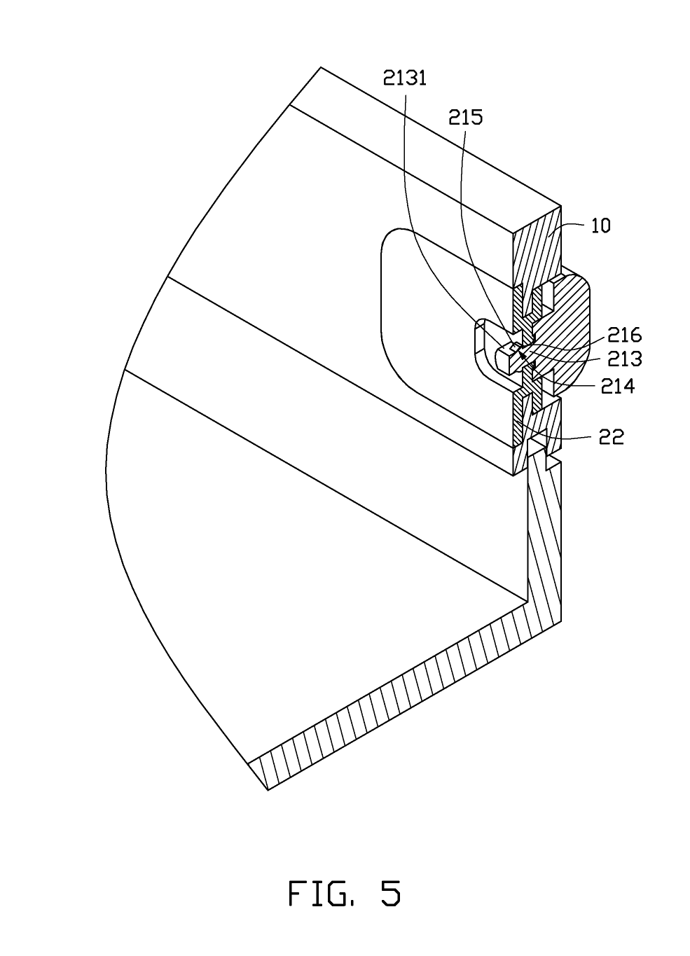

Referring to FIGS. 2-5, in a first embodiment, the button assembly 20 includes a button body 21 and a sealing member 22. The button body 21 includes a cap member 211, a key rod 212, at least one resisting rod 213 and at least one protruding member 214. The key rod 212 and the at least one resisting rod 213 protrude from an inner surface 2111 of the cap member 211. In the embodiment, two resisting rods 213 are employed and the resisting rods 213 are arranged on opposite sides of the key rod 212. In other embodiments, one or more resisting rods 213 may be employed and surrounds the key rod 212.

The at least one protruding member 214 protrudes from a lateral surface 2131 of the at least one resisting rod 213. In the embodiment, two protruding members 214 protrude from opposite lateral surfaces 2131 of one corresponding resisting rod 213.

Each protruding member 214 includes an inclined surface 215 and a resisting surface 216. The inclined surface 215 faces the inside of the housing 10 and is inclined toward the cap member 211. The resisting surface 216 may be perpendicular to the lateral surface 2131 or faces and is inclined toward the cap member 211.

The sealing member 22 and the housing 10 are integrally formed at the opening 101. The sealing member 22 is made of waterproof and elastic material. The sealing member 22 includes a main body 221 and a positioning member 222. The main body 221 is arranged in the opening 101. The positioning member 222 protrudes from the main body 221 toward an inside of the housing 10. The positioning member 222 defines a receiving hole 223. A depth of the receiving hole 223 is equal to a length of the key rod 212. The receiving hole 223 includes an opening end 224 open toward an outside of the housing 10. The key rod 212 is capable of being inserted into the receiving hole 223 through the opening end 224. When the button body 21 is pressed, the key rod 212 of the button body 21 presses the positioning member 222, causing the sealing member 22 to be deformed, thus the positioning member 222 can actuate the switch (not labeled) of the PCB (not labeled).

The sealing member 22 further defines a number of first through holes 225. Each first through hole 225 corresponds to one resisting rod 213. A distance between the resisting surface 216 of the protruding member 214 and the inner surface 2111 of the cap member 211 is less than a length of the first through hole 225. A shape of each first through hole 225 is substantially the same as a shape of corresponding resisting rod 213. In the processing of extending the resisting rod 213 through the corresponding first through hole 225, the rim of each first through hole 225 is pressed by the rim of the corresponding resisting rod 213 and the protruding member 214.

Because of the inclined surface 215, the resisting rod 213 is facilitated extension through the corresponding first through hole 225, and because the material of the sealing member 22 is elastic material, the first through hole 225 enlarges until each protruding member 214 extends through the corresponding first through hole 225. Then the sealing member 22 rebounds and the sealing member 22 is resisted by the resisting surface 216 of each protruding member 214. Thus, the button body 21 is attached to the sealing member 22. Furthermore, the resisting surface 216 of each protruding member 214 resists against the sealing member 22, causing the sealing member 22 to be elastically deformed, thus each resisting rod 213 is tightly engaged in the corresponding first through hole 225. There is no gap between the resisting rod 213 and the corresponding first through hole 225, which prevents water from entering the electronic device 1.

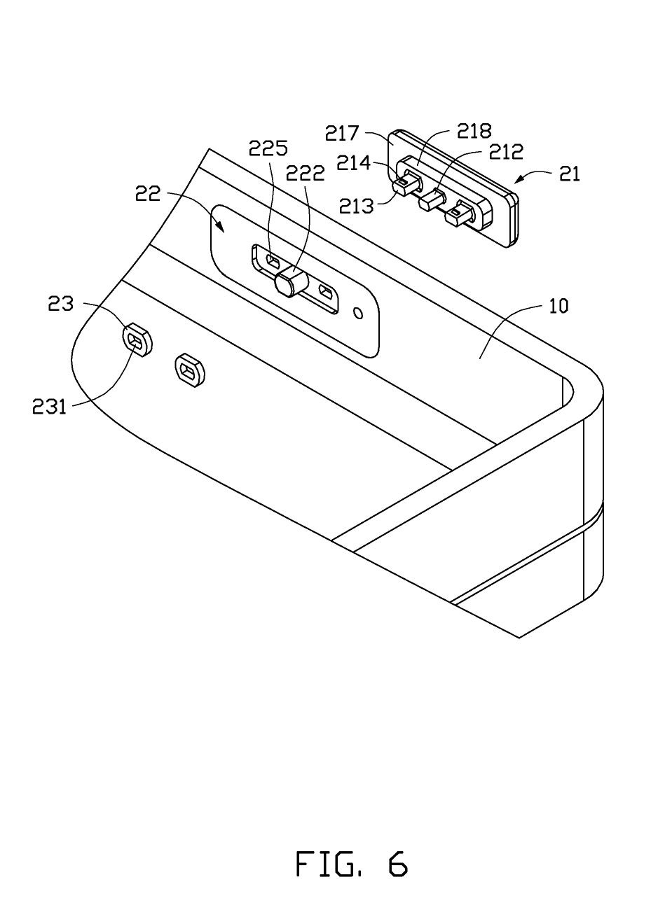

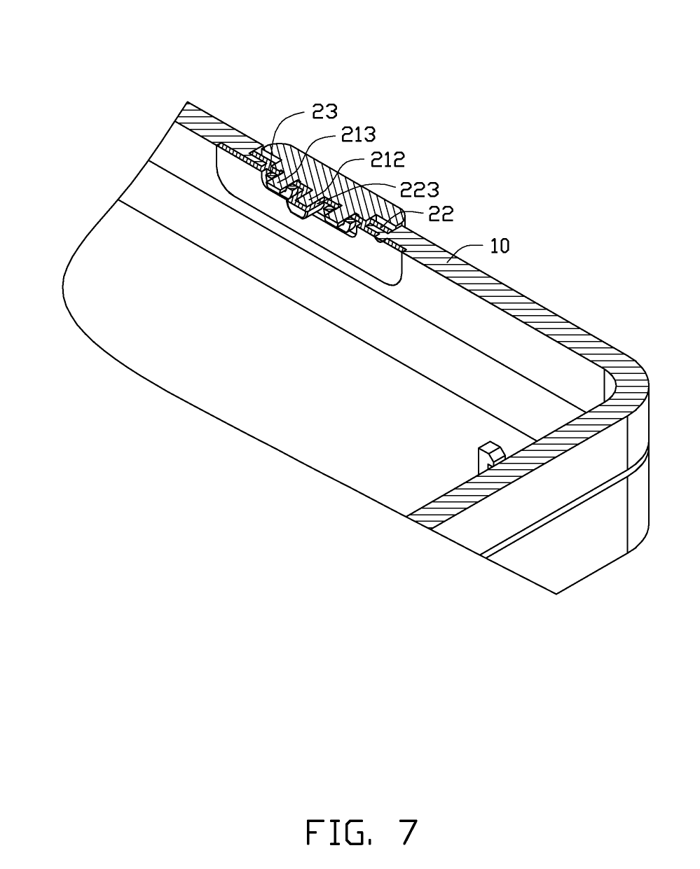

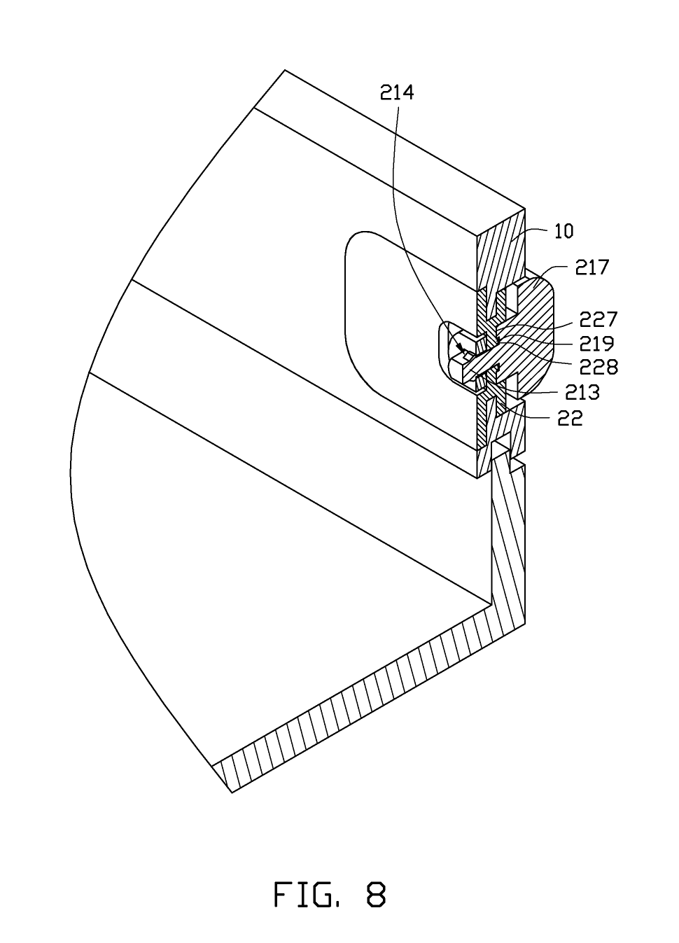

Referring to FIGS. 6-8, in a second embodiment, the button body 21 further includes a number of latching member 23. Each latching member 23 corresponds to one resisting rod 213. Each latching member 23 is made of elastic material. Each latching member 23 defines a second through hole 231. A distance between the resisting surface 216 of the protruding member 214 and the inner surface 2111 of the cap member 211 is less than a total length of the first through hole 225 and the second through hole 231. A shape of each second through hole 231 is substantially the same as a shape of corresponding resisting rod 213. In the processing of extending the resisting rod 213 through the corresponding first through hole 225 and the second through hole 231, the rim of each first through hole 225 and each second through hole 231 are pressed by the rim of the corresponding resisting rod 213 and the protruding member 214. Because of the inclined surface 215 and the material of the sealing member 22, each first through hole 225 and each second through hole 231 enlarges until each protruding member 214 extends through the corresponding first through hole 225 and the corresponding second through hole 231. Then the sealing member 22 and each latching member 23 rebound, and each latching member 23 resists against the resisting surface 216 of corresponding protruding member 214. Thus, the button body 21 is attached to the sealing member 22.

Further, the resisting surface 216 of each protruding member 214 resists against the corresponding latching member 23, the latching members 23 and the sealing member 22 are elastically deformed. Thus each resisting rod 213 is tightly engaged in the corresponding first through hole 225 and the corresponding second through hole 231. There is no gap between the resisting rod 213 and the corresponding first through hole 225 or the corresponding second through hole 231, which prevents water from entering the electronic device 1. Also, the resisting surface 216 of each protruding member 214 is resisted against the corresponding latching member 23. Thus the force exerted on the latching member 23 is uniformly exerted on the sealing member 22, which prevents the sealing member 22 from being damaged.

In the aforementioned first embodiment and second embodiment, the cap member 211 includes a base 217 and a sealing portion 218. The sealing portion 218 protrudes from the base 217. The key rod 212 and the resisting rods 213 protrude from a sidewall of the sealing portion 218 away from the base 217. The sidewall of the sealing portion 218 further defines a number of first annular grooves 219 surrounding the corresponding resisting rod 213. The sealing member 22 defines a number of recesses 227 engagingly receiving the sealing portion 218 and forms a number of annular protrusions 228 extending from a bottom in the recess. Each annular protrusion 228 is tightly engaged in the corresponding first annular groove 219 of the sealing portion 218.

After the button body 21 is attached to the sealing member 22, each recess 227 of the sealing member 22 is urged to deform by the resisting surface 216, thus each annular protrusion 228 of the sealing member 22 tightly engages in the corresponding first annular groove 219 of the sealing portion 218, and the sealing portion 218 tightly engages in the corresponding second recess 227 of the sealing member 22, which further prevents water from entering the electronic device 1.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A waterproof button assembly for an electronic device, the electronic device comprising a housing defining an opening, the button assembly comprising:
a button body comprising a cap member, a key rod, at least one resisting rod, and at least one protruding member, the key rod and the at least one resisting rod protruding from an inner surface of the cap member, the at least one protruding member protruding from a lateral surface of the resisting rod, each of the at least one protruding member comprising a resisting surface; and
a sealing member configured to be integrally formed with the housing at the opening, the sealing member being made of waterproof and elastic material, and comprising a main body configured for being arranged in the opening and a positioning member protruding from the main body toward an inside of the housing, the positioning member defining a receiving hole, the receiving hole comprising an opening end open toward an outside of the housing, the key rod being inserted in the receiving hole through the opening end, the sealing member defining at least one first through hole, each of the at least one resisting rod extending through the corresponding first through hole, the sealing member being elastically deformed by engagement with the resisting surface of the protruding member, and each of the at least one first through hole being tightly engaged with the corresponding resisting rod.

2. The waterproof button assembly as described in claim 1, wherein each of the protruding member comprises an inclined surface facing the inside of the housing and being inclined toward the cap member, each of the inclined surface is configured for facilitating extension of the resisting rod through the corresponding first through hole.

3. The waterproof button assembly as described in claim 1, wherein a distance between the resisting surface of the protruding member and the inner surface of the cap member is less than a length of the first through hole; whereby after each of the resisting rod extends through the corresponding first through hole, the inner surface of the sealing member resists against the resisting surface of each protruding member, the sealing member is elastically deformed, and each resisting rod is tightly engaged in the corresponding first through hole.

4. The waterproof button assembly as described in claim 1, wherein the button body further comprises at least one latching member corresponding to the at least one resisting rod, each of the at least one latching member defines a second through hole; a distance between the resisting surface of the protruding member and the inner surface of the cap member is less than a total length of the first through hole and the second through hole; whereby after each of the resisting rod extends through the corresponding first through hole and the corresponding second through hole, each of the at least one latching member resists against the resisting surface of the corresponding protruding member, the sealing member and the at least one latching member are elastically deformed, and each resisting rod is tightly engaged in the corresponding first through hole and the corresponding second through hole.

5. The waterproof button assembly as described in claim 1, wherein the cap member comprises a base and a sealing portion, the sealing portion protrudes from the base, the sealing portion defines at least one first annular groove surrounding the corresponding resisting rod; the sealing member comprises at least one recess engagingly receiving the sealing portion and at least one annular protrusion extending from a bottom in the recess, the at least one annular protrusion tightly engaging in the corresponding first annular groove of the sealing portion.

6. The waterproof button assembly as described in claim 1, wherein a shape of each of the at least one first through hole is the same as a shape of corresponding resisting rod.

7. The waterproof button assembly as described in claim 1, wherein a depth of the receiving hole is equal to a length of the key rod.

8. The waterproof button assembly as described in claim 1, wherein the resisting surface may be perpendicular to the lateral surface or faces and is inclined toward the cap member.

9. An electronic device comprising:
a housing defining an opening; and
a button body comprising a cap member, a key rod, at least one resisting rod, and at least one protruding member, the key rod and the at least one resisting rod protruding from an inner surface of the cap member, the at least one protruding member protruding from a lateral surface of the resisting rod, each of the at least one protruding member comprising a resisting surface; and
a sealing member integrally formed with the housing at the opening, the sealing member being made of waterproof and elastic material, and comprising a main body arranged in the opening and a positioning member protruding from the main body toward an inside of the housing, the positioning member defining a receiving hole, the receiving hole comprising an opening end open toward an outside of the housing, the key rod being inserted in the receiving hole through the opening end, the sealing member defining at least one first through hole, each of the at least one resisting rod extending through the corresponding first through hole, the sealing member being elastically deformed by engagement with the resisting surface of the protruding member, and each of the at least one first through hole being tightly engaged with the corresponding resisting rod.

10. The electronic device as described in claim 9, wherein each of the protruding member comprises an inclined surface facing the inside of the housing and being inclined toward the cap member, each of the inclined surface is configured for facilitating extension of the resisting rod through the corresponding first through hole.

11. The electronic device as described in claim 9, wherein a distance between the resisting surface of the protruding member and the inner surface of the cap member is less than a length of the first through hole; whereby after each of the resisting rod extends through the corresponding first through hole, the inner surface of the sealing member resists against the resisting surface of each protruding member, the sealing member is elastically deformed, and each resisting rod is tightly engaged in the corresponding first through hole.

12. The electronic device as described in claim 9, wherein the button body further comprises at least one latching member corresponding to the at least one resisting rod, each of the at least one latching member defines a second through hole; a distance between the resisting surface of the protruding member and the inner surface of the cap member is less than a total length of the first through hole and the second through hole; whereby after each of the resisting rod extends through the corresponding first through hole and the corresponding second through hole, each of the at least one latching member resists against the resisting surface of the corresponding protruding member, the sealing member and the at least one latching member are elastically deformed, and each resisting rod is tightly engaged in the corresponding first through hole and the corresponding second through hole.

13. The electronic device as described in claim 9, wherein the cap member comprises a base and a sealing portion, the sealing portion protrudes from the base, the sealing portion defines at least one first annular groove surrounding the corresponding resisting rod, the sealing member comprises at least one recess engagingly receiving the sealing portion and at least one annular protrusion extending from a bottom in the recess, the at least one annular protrusion tightly engaging in the corresponding first annular groove of the sealing portion.

14. The electronic device as described in claim 9, wherein a shape of each of the at least one first through hole is the same as a shape of corresponding resisting rod.

15. The electronic device as described in claim 9, wherein a depth of the receiving hole is equal to a length of the key rod.

16. The electronic device as described in claim 9, wherein the resisting surface may be perpendicular to the lateral surface or faces and is inclined toward the cap member.
